(19) United States
(12) Patent Application Publication
(10) Pub. No.: US 2009/0250236 A1
(43) Pub. Date: Oct. 8, 2009

(54) FLEXIBLE MECHANICAL PACKAGING FORM FACTOR FOR RACK MOUNTED COMPUTING DEVICES

(75) Inventors: Michael Corwin, Sunnyvale, CA (US); Duong Nguyen, Santa Clara, CA (US); Joseph I. Chamdani, Santa Clara, CA (US)

Correspondence Address: KNOBBE MARTENS OLSON & BEAR LLP, 2040 MAIN STREET, FOURTEENTH FLOOR, IRVINE, CA, 92614, US

(73) Assignee: Kickfire, Inc., Santa Clara, CA (US)

(21) Appl. No.: 12/098,988

(22) Filed: Apr. 7, 2008

(51) Int. Cl. H05K 5/00; H01R 13/46

(52) U.S. Cl. 174/59; 174/50

(57) ABSTRACT

The present invention comprises a dual-use form factor for rack mounting equipment. In particular, the form-factor is configured so that it can be both rack-mounted directly or installed within a chassis. In addition, the form-factor may comprise one or more blind-mate connector systems that are suitable for blunt-type connectors, such as PCIe connectors.

### BACKGROUND

Today, in data centers, the equipment is mounted on racks. Commonly, a 19-inch rack is the standard system for mounting various electronic modules in a “stack”, or rack, which is 19 inches wide. Accordingly, equipment is now designed to be placed in a rack and is typically described as rack-mount, a rack mounted system, a rack mount chassis, subrack, or occasionally, simply shelf. In generally, a subrack or 1U is 1.75 inches in height and is often referred to as a “pizza box” due to the similarity in size and shape.

Most racks are sold in the 42U form: that is, a single rack capable of holding 42 1U pizza box servers. Because of their origin as mounting systems for railroad signaling relays, they are still sometimes called relay racks, but the 19-inch rack format has remained a constant while the technology that is mounted within it has changed to completely different fields. This standard rack arrangement is widely used throughout the telecommunications, computing, audio, and other industries.

The rack's mounting fixture consists of two parallel metal strips (also referred to as “rails” or “panel mount”) standing vertically. The strips are separated by a gap of 17.75 inches, giving an overall rack width of 19 inches. The strips have holes in them at regular intervals, with both strips matching, so that each hole is part of a horizontal pair with a center-to-center distance of 18.3 inches.

The holes in the strips are arranged vertically in repeating sets of three, with center-to-center separations of 0.5 inch, 0.625 inch, and 0.625 inch. The hole pattern thus repeats every 1.75 inches. Racks are divided into regions, 1.75 inches in height, within which there are three complete hole pairs in a vertically symmetric pattern. Such a region is commonly known as a “U”, for “unit”, and heights within racks are measured by this unit. Rack-mountable equipment is usually designed to occupy some integral number of U.

Computer servers designed for rack mounting often include a number of extra features to make the server easy to use in the rack. Sliding rails can lock in the extended position to prevent the equipment from moving when extended out from the rack into the service position. A rack mounted server often has locking pins on the sides that just drop into slots on the extended rail assembly. This permits a very easy server installation and removal since there is no need for the server to be held in midair while someone fastens each rail to the sides of the server with screws.

The rack mount hardware often includes a folding cable tray behind the server, so that the cables are held into a neat and tidy folded channel when inside the rack, and unfolds out into a long strip when pulled out of the rack, allowing the server to continue to be plugged in and operating normally even while fully extended and hanging in midair in front of the rack. This cable tray also helps prevent a huge cable tangle from forming at the rear of the rack, as unbound cables from upper equipment drape down onto equipment below.

Conventional rack mounted devices come in basically two varieties. The first variety is a 1U variety, which means that the devices are individually mounted to the rack. In this configuration, the form factor of the device is designed to directly mount to the rack. The second variety is a chassis mount. In this configuration, a chassis taking up several U on the rack is installed. The devices then have a different form factor that is designed to mount to the chassis, not the rack.

Unfortunately, this system makes is difficult to scale a system. For example, if an enterprise initially installs the 1U variety, then they are forced to cobble together a plurality of units as the system grows. The 1U variety devices are not compatible with the chassis. Alternatively, if the user wants to use a chassis mount, an enterprise must pay significantly more for the devices due to the more complex mounting hardware.

Therefore, it would desirable to provide a mechanical packaging that is flexible and scalable from 1U to multiple Us, regardless of whether the device is individually mounted or chassis mounted.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1 illustrates a front view of a 5U chassis of the present invention;

FIG. 2 illustrates a rear view of the 5U chassis of FIG. 1;

FIG. 3 illustrates a front view of a 2U chassis of the present invention

FIG. 4 illustrates a rear view of the 2U chassis of FIG. 3;

FIG. 5 shows a blind mate connector with the connector in its installed position;

FIG. 6 shows a side view of the blind mate connector; and

FIG. 7 shows a break-out view of the blind mate connector.

### DETAILED DESCRIPTION

The present invention comprises a dual-use form factor for rack mounting equipment. In particular, the form-factor is configured so that it can be both rack-mounted directly or installed within a chassis. In addition, the form-factor may comprise one or more blind-mate connector systems that are suitable for blunt-type connectors, such as PCIe connectors.

Reference will now be made in detail to the exemplary embodiments of the invention, which are illustrated in the accompanying drawings. Wherever possible, the same reference numbers will be used throughout the drawings to refer to the same or like parts.

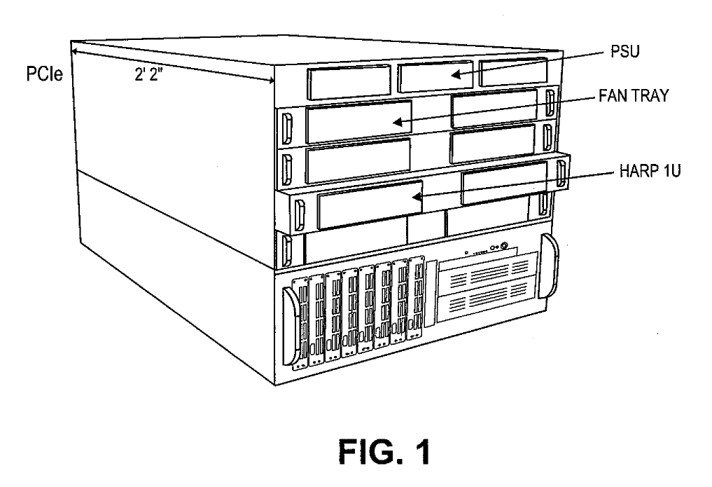

As shown, FIG. 1 illustrates a front view of a 5U chassis. In the embodiment shown, the chassis may comprise a power module and integrated fans. In addition, the 5U chassis may comprise 4 slots for modules (each 1U). In the present invention, the 5U chassis is configured to accommodate 1U form factors that also can be directly rack mounted. Thus, the mechanical packaging form factor of the present invention can accommodate dual-uses, i.e., loose rack-mount or chassis mount.

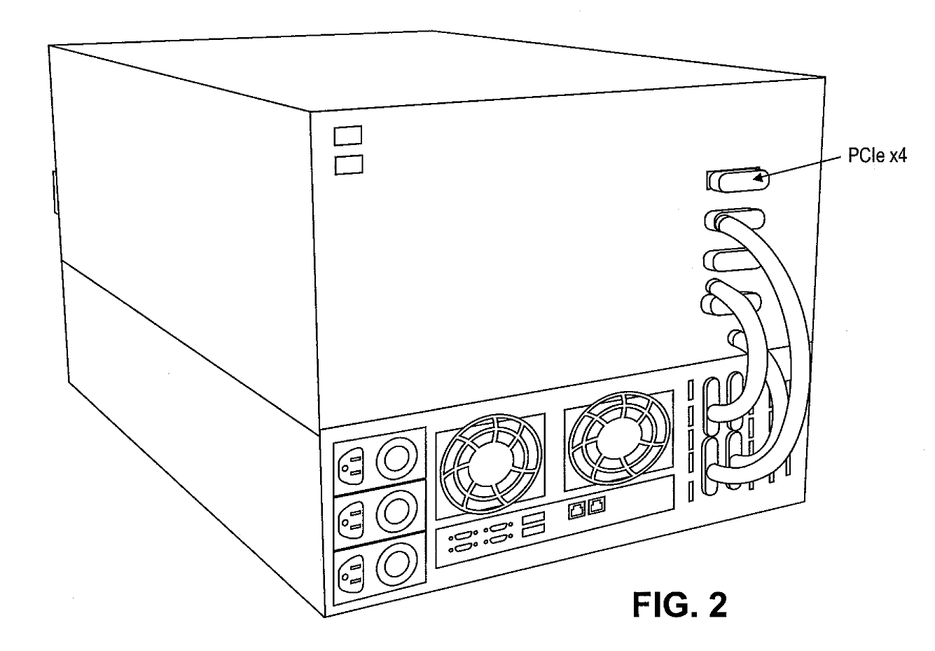

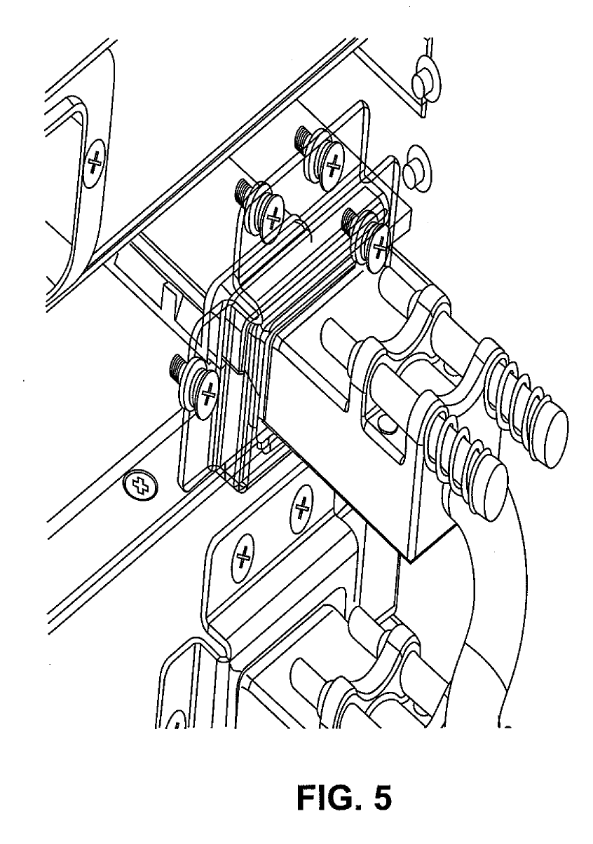

FIG. 2 illustrates a rear view of the 5U chassis shown in FIG. 1. As shown, the chassis may comprise connectors for one or more interconnects, such as PCIe interconnects. This allows for 1U modules to be docked into the chassis without having to recable the backside of the chassis and allows for front-side servicing. The features of the PCIe interconnect are described further with reference to FIGS. 5-7.

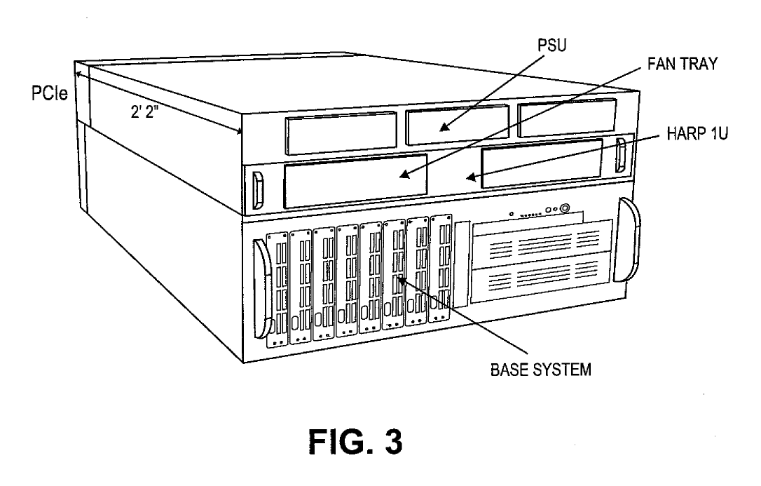

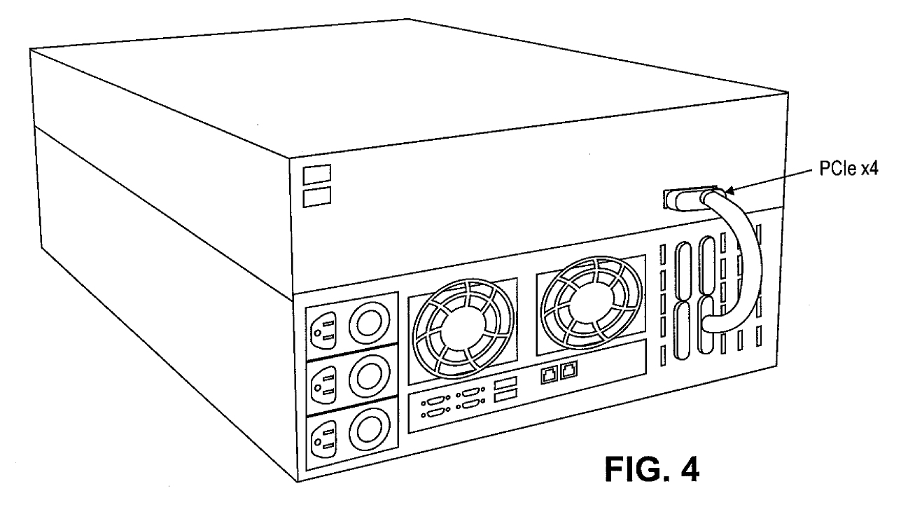

FIG. 3 illustrates a 2U chassis of the present invention. As shown, the chassis may comprise a power module, integrated fans, and 1 slot for a 1U module. FIG. 4 shows a rear view of the 2U chassis shown in FIG. 3. Of note, both the 2U and 5U chassis are similar. For example, both chassis can accommodate the same module. This feature is significant because it allows for modular scaling up (and down) using the same 1U module.

In the present invention, the 1U module is standard 1U Height, but may be slightly smaller in width to accommodate a potential chassis mount. However, the 1U module is sized so that it can also be rack mounted directly.

As shown in FIGS. 2 and 4, each 1U module may also comprise one or more blind-mate connectors. In some embodiments, the blind-connector is for a PCIe connector. However, any type of connector may be employed in the present invention.

Exemplary blind mate connectors of the present invention will now be described with reference to FIGS. 5-7. As can be seen in the following figures, the present invention may be usefully for “blunt” or squarish connectors, such as the typical PCIe connector. Other examples of squarish connectors include USB connectors.

FIG. 5 shows a blind mate connector with the connector in its installed position. As shown, the connector may be held in place by one or more spring loaded screws. The chassis may comprise a mounting bracket held into place by a set of screws. The female end of the connector exists on the module. Of note, since the female end and the mounting bracket are spaced apart, this allows for mechanical variance when inserting the male end of the connector.

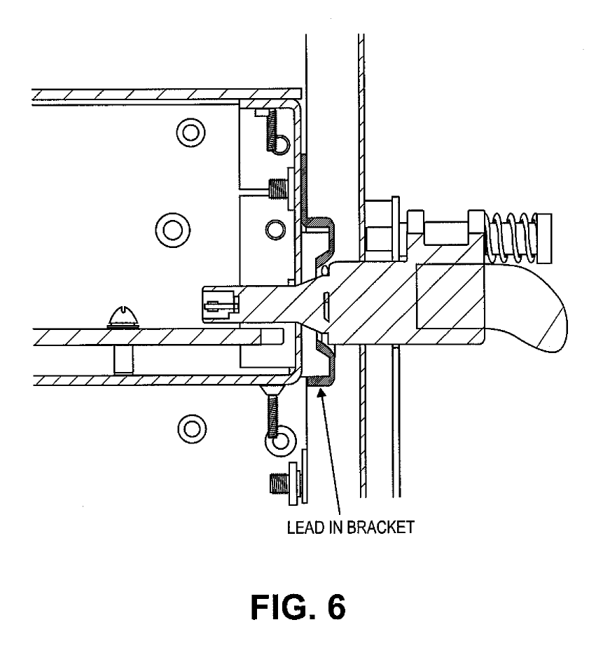

FIG. 6 shows a side view of the blind mate connector with the connector in its installed position. From this side view, it can be seen that the 1U module may comprise a lead in bracket. This lead in bracket provides a guide or funneling surface that assists in homing the male end of the connector into the female end. As previously noted, the 1U module is floating relatively to the chassis itself, which allows for mechanical variance or “play” in aligning the connector.

As can also be seen, the connector is spring loaded so that a tactile force is required to engage the connector into its installed position. This feature may be useful in a rack-mounting environment because often the connector is installed by feel rather than visually. The spring loaded engagement also provides tactile confirmation that the connector has been engaged.

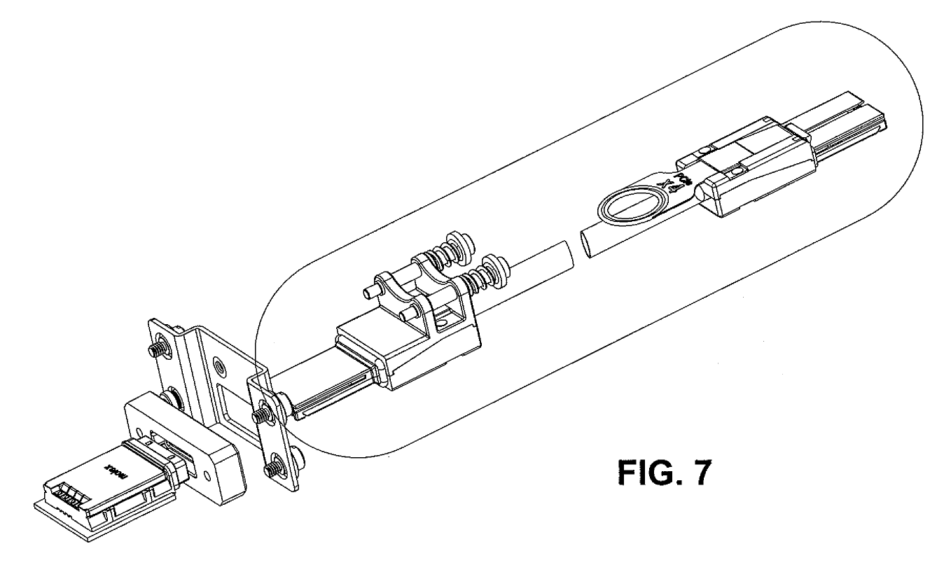

FIG. 7 shows the blind mate connector and its various components. As shown, on the far left, the connector may comprise a guide housing. Next, a guiding block is provided. As noted with reference to FIG. 6, this structure provides a lead in bracket and guide surface for installing the connector. The mounting bracket for the chassis is then shown to illustrate how the guiding block can “float” relative to the mounting bracket. Finally, a PCIe cable and wiring assembly is shown.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A 1U module, said module comprising:
a form factor that can accommodate both rack mounting directly and mounting into a chassis; and
a blind mate connector.

2. The 1U module of claim 1, wherein the blind mate connector is a PCIe connector.

3. A mounting frame system, said system comprising:
an open front-side that permits docking of at least one module and access to the at least one module; and
a back-side having a set of cabling interfaces that are configured to be blindly coupled to the at least one module, while maintaining connections of cables to the cabling interface.

4. A modular mounting system, said system comprising:
a first section configured to hold a host system; and
a second section having a plurality of sizes that can be mated to the first section.

5. A module, said module comprising:
a form factor that can accommodate both rack mounting directly and mounting into a chassis; and
a set of connectors that support blind mate and direct cable attachment.

6. The module of claim 5, wherein the module provides power to other modules via a blind mate connector that can connect to the other module.

7. The module of claim 5, wherein the modules comprise a communication hub for other modules to connect to a host processor.

8. The module of claim 1, wherein at least one of the set of connectors is a PCIe connector.

9. The module of claim 1, wherein at least one of the set of connectors is a combination power and signal connector.

10. The module of claim 1, wherein at least one of the set of connectors is a AC power connector.
